(19) United States
(12) Patent Application Publication
(10) Pub. No.: US 2026/0123557 A1
(43) Pub. Date: Apr. 30, 2026

(54) CHIP PACKAGE STRUCTURE, MANUFACTURING METHOD AND HALF BRIDGE MODULE OF INVERTER

(71) Applicant: ZF Friedrichshafen AG, Friedrichshafen (DE)

(72) Inventors: Qing Xu, Shanghai (CN); Shaozhi Yuan, Shanghai (CN)

(73) Assignee: ZF Friedrichshafen AG, Friedrichshafen (DE)

(21) Appl. No.: 19/371,852

(22) Filed: Oct. 28, 2025

(30) Foreign Application Priority Data
Oct. 28, 2024 (CN) 202411513791.8

(51) Int. Cl. H01L 23/495; H01L 23/00

(52) U.S. Cl. CPC H10W 90/811; H10W 72/07331; H10W 90/736

(57) ABSTRACT

A chip packaging structure includes a busbar with a plurality of chip slots; a plurality of chip units respectively embedded into the plurality of chip slots, and including at least two different types of chip units, with electrochemical plating arranged at a bottom of the chip slot, and the chip unit includes a conductive layer, a chip main body, and a DTS layer sequentially stacked on the plating; and a channel arranged on the busbar and located between adjacent chip slots. By integrating and embedding the different types of chip units into the same busbar, subsequent manufacturing of a circuit board is facilitated. Additionally, the channel absorbs busbar thermal expansion caused by heat generated during operation of the chip units, and reduces thermal coupling between the chip units, thereby preventing the chip units from interfering with each other, and ensuring firm positions and stable performance of the chip units.

### CROSS-REFERENCE TO RELATED APPLICATION

This application claims priority to Chinese Patent Application No. 202411513791.8, filed on Oct. 28, 2024, the entirety of which is hereby fully incorporated by reference herein.

### TECHNICAL FIELD

The present disclosure relates to the technical field of automotive parts, and particularly relates to a chip packaging structure, a manufacturing method, and a half-bridge module for an inverter.

### BACKGROUND

In inverters and other automotive parts, different types of chips are required to be used. Currently, various chips are usually packaged separately, which makes it inconvenient to manufacture circuit boards for the automotive parts.

Taking inverters as an example, in order to adapt to different load conditions such as high voltage (typically 800 V) and low voltage (typically 400 V), at present, silicon carbide (SiC) chips and insulated gate bipolar transistor (IGBT) chips are usually arranged in parallel in high-quality inverters, such that the performance of the inverters is improved and the cost is reduced by making full use of the characteristics of high-voltage resistance and the like of the SiC chips and the characteristics of low power consumption and the like of the IGBT chips.

However, SiC chips, IGBT chips and other different types of chips are currently packaged separately, and thus there are problems such as a large number of parts, complicated process and inconvenient wiring during the process of manufacturing the circuit boards for inverters.

It should be noted that information disclosed in the above background art section is only used to enhance the understanding of the background of the present disclosure, and therefore may include information that does not constitute the prior art known to those of ordinary skill in the art.

### SUMMARY

In view of this, the present disclosure provides a chip packaging structure, a manufacturing method, and a half-bridge module for an inverter, which can integrate and embed different types of chip units into the same busbar to facilitate subsequent manufacturing of a circuit board and to solve the problems such as a large number of parts, complicated process, and inconvenient wiring during the process of manufacturing circuit boards for inverters and other automotive parts.

According to an aspect of the present disclosure, a chip packaging structure is provided, including: a busbar provided with a plurality of chip slots; a plurality of chip units respectively embedded into the plurality of chip slots, the plurality of chip units including at least two different types of chip units, where an electrochemical plating is arranged at a bottom of the chip slot, and the chip unit includes a conductive layer, a chip main body and a DTS layer sequentially stacked on the electrochemical plating; and a channel arranged on the busbar and located between adjacent chip slots.

In some embodiments, the channel has a length equal to a length of the chip slot, and/or the channel has a width which is ⅓ to ½ of a spacing between the adjacent chip slots, and/or the channel has a depth greater than a depth of the chip slot.

In some embodiments, the length L of the channel meets: 7 mm≤L≤8 mm, and/or the width W of the channel meets: 1 mm≤W≤1.5 mm, and/or the depth D of the channel meets: 0.25 mm≤D≤0.5 mm.

In some embodiments, an area of a projection of the electrochemical plating on the bottom of the chip slot is greater than an area of a projection of the chip unit on the bottom of the chip slot, and the electrochemical plating is spaced from a peripheral wall of the chip slot.

In some embodiments, a spacing S1 between the chip unit and the peripheral wall of the chip slot meets: 0.5 mm≤S1≤1 mm, and/or a distance S2 by which an edge of the electrochemical plating extends beyond an edge of the chip unit meets: 5 μm≤S2≤10 μm.

In some embodiments, the electrochemical plating has a thickness of 5 μm to 10 μm, and/or the conductive layer has a thickness of 40 μm to 60 μm, and/or the chip main body has a thickness of 180 μm, and/or the DTS layer has a thickness of 40 μm to 50 μm.

In some embodiments, the chip units on the busbar include a SiC chip unit and an IGBT chip unit, where each of the SiC chip unit and the IGBT chip unit has a gate and a source both formed on a front side and a drain formed on a back side, and the SiC chip unit and the IGBT chip unit share the busbar as the drains.

According to another aspect of the present disclosure, a method for manufacturing a chip packaging structure of any one of the above embodiments is provided, the manufacturing method including: forming a plurality of chip slots and a channel in a busbar, where the channel is located between adjacent chip slots; forming an electrochemical plating at a bottom of each of the chip slots; sequentially stacking a conductive layer, a chip main body and a DTS layer of a chip unit on each of the electrochemical platings; and performing a single sintering process on the chip units and the busbar to form the chip packaging structure.

In some embodiments, the single sintering process is performed at a pressure of 20 MPa to 25 MPa and a temperature of 200° C. to 250° C.

In some embodiments, during the single sintering process, a cushioned pressure head is pressed onto the chip units and the busbar.

According to yet another aspect of the present disclosure, a half-bridge module for an inverter is provided, the half-bridge module including: a circuit board; two chip packaging structures of any one of the above embodiments embedded into the circuit board, where a triode chip unit is embedded in each of the chip packaging structures; and electrode lead-out wires, including a source lead-out wire connected to a source of the triode chip unit of a first chip packaging structure, gate lead-out wires respectively connected to a gate of the triode chip unit of the first chip packaging structure and a gate of the triode chip unit of a second chip packaging structure, a series connection lead-out wire for connecting a drain of the triode chip unit of the first chip packaging structure in series with a source of the triode chip unit of the second chip packaging structure, and a drain lead-out wire connected to a drain of the triode chip unit of the second chip packaging structure.

In some embodiments, a busbar of each of the chip packaging structures is provided with a stepped portion.

Compared with the prior art, the present disclosure has at least the following beneficial effects.

In the chip packaging structure according to the present disclosure, the plurality of chip units are embedded into the same busbar, where the two different types of chip units include, for example, the SiC chip unit and the IGBT chip unit, such that the different types of chip units are integrated and embedded into the same busbar to facilitate subsequent manufacturing of a circuit board and to solve the problems such as a large number of parts, complicated process, and inconvenient wiring during the process of manufacturing circuit boards for inverters and other automotive parts.

In addition, in the chip packaging structure according to the present disclosure, the channel is arranged between adjacent chip slots of the busbar, and the channel can absorb thermal expansion of the busbar caused by heat generated during operation of the chip units, and reduce thermal coupling between the chip units, thereby preventing the chip units from interfering with each other and ensuring firm positions and stable performance of the chip units.

It should be understood that the above general description and the following detailed description are only exemplary and explanatory, and cannot limit the present disclosure.

The accompanying drawings herein, which are incorporated into and constitute a part of the description, illustrate embodiments consistent with the present disclosure and, together with the description, are used to explain principles of the present disclosure. Obviously, the accompanying drawings described below show merely some of the embodiments of the present disclosure, and those of ordinary skill in the art would also have obtained other accompanying drawings according to these accompanying drawings without any creative effort.

### BRIEF DESCRIPTION OF THE DRAWINGS

FIG. 1 is a schematic diagram of a three-dimensional structure of a chip packaging structure according to an embodiment of the present disclosure;

FIG. 2 is a schematic diagram of a partial exploded structure of the chip packaging structure according to an embodiment of the present disclosure;

FIG. 3 is a schematic diagram of a partial sectional structure of the chip packaging structure according to an embodiment of the present disclosure;

FIG. 4 is a schematic diagram of a top-view structure of another chip packaging structure according to an embodiment of the present disclosure;

FIG. 5 is a schematic diagram showing steps of a method for manufacturing a chip packaging structure according to an embodiment of the present disclosure;

FIG. 6 is a schematic diagram of the chip packaging structure during sintering according to an embodiment of the present disclosure; and

FIG. 7 is a schematic diagram of a sectional structure of a half-bridge module for an inverter according to an embodiment of the present disclosure.

### DETAILED DESCRIPTION

Now exemplary implementations will be described more fully with reference to the accompanying drawings. However, the exemplary implementations can be implemented in many forms and should not be construed as being limited to the implementations described herein. On the contrary, these implementations are provided to make the present disclosure more thorough and complete, and to fully convey the concept of the exemplary implementations to those skilled in the art.

The accompanying drawings are only schematic illustrations of the present disclosure, and are not necessarily drawn to scale. In the accompanying drawings, the same reference numerals denote the same or similar parts, and thus the repeated description thereof will be omitted. In addition, the process shown in the accompanying drawings is only an exemplary illustration, and does not necessarily include all steps. For example, some steps can be divided, and some steps can be combined or partially combined, and the actual execution order thereof may be changed based on actual conditions.

The terms “first”, “second” and similar terms used in the specific description do not denote any order, quantity, or importance, but are merely used to distinguish between different components. Orientations or positional relationships indicated by the terms such as “upper”, “lower”, “front” and “back” are based on orientations or positional relationships shown in the drawings, which is only for convenience of describing the present disclosure and simplifying the description, rather than indicating or implying that an apparatus or an element referred to must have a specific orientation or be constructed and operated in a specific orientation, and therefore cannot be construed as limiting the present disclosure. The term “a plurality of” means two or more, unless otherwise explicitly and specifically defined. Moreover, in the description of the disclosure, when it is said that a device is “connected” to another device, this includes not only the case of direct connection but also the case of indirect connection through other elements.

It should be noted that the embodiments in the present disclosure and features of the various embodiments can be combined with each other without conflict.

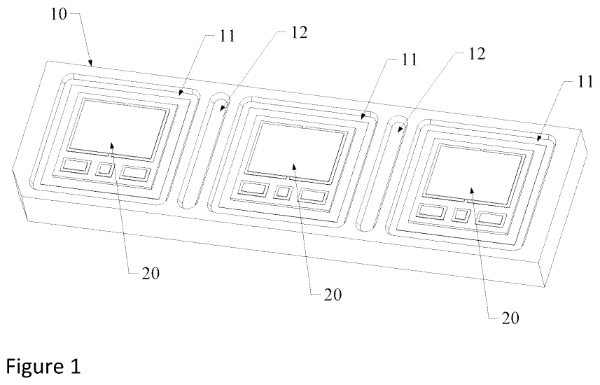

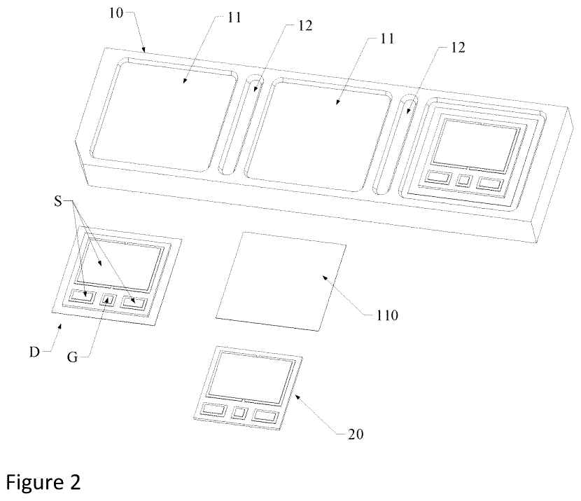

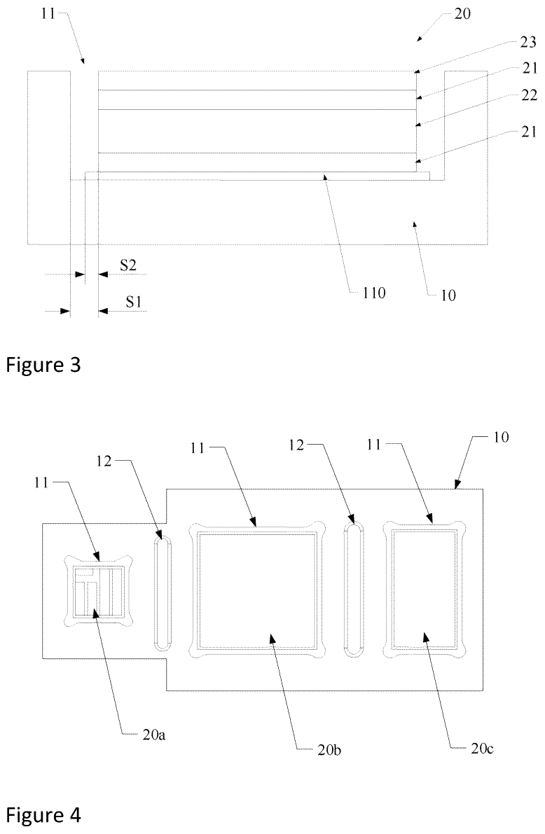

FIG. 1 illustrates a three-dimensional structure of a chip packaging structure, FIG. 2 illustrates a partial exploded structure of the chip packaging structure, FIG. 3 illustrates a partial sectional structure of the chip packaging structure, and FIG. 4 illustrates a top-view structure of another chip packaging structure. With reference to FIGS. 1 to 4, the chip packaging structure according to an embodiment of the present disclosure includes:
a busbar 10, the busbar 10 being provided with a plurality of chip slots 11;
a plurality of chip units 20 respectively embedded into the plurality of chip slots 11, the plurality of chip units 20 including at least two different types of chip units,
where an electrochemical plating 110 is arranged at a bottom of the chip slot 11, and the chip unit 20 includes a conductive layer 21, a chip main body 22 and a die top system (DTS) layer 23 sequentially stacked on the electrochemical plating 110; and
a channel 12 arranged on the busbar 10 and located between adjacent chip slots 11.

The busbar 10 is, for example, a copper busbar. The electrochemical plating 110 mainly forms metal deposition at the bottom of the chip slot 11 through electrochemical reaction. The conductive layer 21 may be a silver film. The chip main body 22 includes an insulating layer and electrodes, such as a gate, a source and a drain, attached to the insulating layer. The DTS layer 23 is formed based on the die top system technology and includes a copper sheet and a pre-coated silver layer attached to the copper sheet.

FIGS. 1 and 4 illustrate that three chip units 20 are provided on the busbar 10, without being limited thereto. The number, sizes, types, etc. of the chip units 20 integrated on the busbar 10 can be adjusted as required according to different design requirements.

In the chip packaging structure according to the present disclosure, the plurality of chip units 20 are embedded into the same busbar 10, where the two different types of chip units include a SiC chip unit 20a and an IGBT chip unit 20b, such that the different types of chip units 20 are integrated and embedded into the same busbar 10 to facilitate subsequent manufacturing of a circuit board and to solve the problems such as a large number of parts, complicated process, and inconvenient wiring during the process of manufacturing circuit boards for inverters and other automotive parts.

In addition, in the chip packaging structure according to the present disclosure, the channel 12 is arranged between adjacent chip slots 11 of the busbar 10, and the channel 12 can absorb thermal expansion of the busbar 10 caused by heat generated during operation of the chip units 20, and reduce thermal coupling between the chip units 20, thereby preventing the chip units 20 from interfering with each other and ensuring firm positions and stable performance of the chip units 20.

In some embodiments, the channel 12 has a length equal to a length of the chip slot 11, and/or the channel 12 has a width which is ⅓ to ½ of a spacing between the adjacent chip slots 11, and/or the channel 12 has a depth greater than a depth of the chip slot 11.

The length, the width and the depth of the channel 12 are designed to ensure that the channel 12 can stably play the roles of absorbing thermal expansion and reducing thermal coupling.

In some embodiments, the length (defined as L) of the channel 12 meets: 7 mm≤L≤8 mm, for example, the length L of the channel 12 is 7 mm, 7.6 mm, 8 mm, etc.; and/or the width (defined as W) of the channel 12 meets: 1 mm≤W≤1.5 mm, for example, the width W of the channel 12 is 1 mm, 1.2 mm, 1.5 mm, etc.; and/or the depth (defined as D) of the channel 12 meets: 0.25 mm≤D≤0.5 mm, for example, the depth D of the channel 12 is 0.25 mm, 0.38 mm, 0.5 mm, etc.

In some embodiments, an area of a projection of the electrochemical plating 110 on the bottom of the chip slot 11 is greater than an area of a projection of the chip unit 20 on the bottom of the chip slot 11, and the electrochemical plating 110 is spaced from a peripheral wall of the chip slot 11.

The electrochemical plating 110 plays a transitional role and serves a sintering process of the chip unit 20. With the design in which the area of the projection of the electrochemical plating 110 is greater than the area of the projection of the chip unit 20 and the electrochemical plating 110 is spaced from the peripheral wall of the chip slot 11, it is ensured that the chip unit 20 can be sintered and fixed in the chip slot 11, and the electrochemical plating 110 is prevented from contacting the peripheral wall of the chip slot 11 to cause a short circuit.

In some embodiments, a spacing S1 between the chip unit 20 and the peripheral wall of the chip slot 11 meets: 0.5 mm≤S1≤1 mm, and/or a distance S2 by which an edge of the electrochemical plating 110 extends beyond an edge of the chip unit 20 meets: 5 μm≤S2≤10 μm.

In this way, the design is achieved where the area of the projection of the electrochemical plating 110 is greater than the area of the projection of the chip unit 20 and the electrochemical plating 110 is spaced from the peripheral wall of the chip slot 11. The spacing S1 between the chip unit 20 and the peripheral wall of the chip slot 11 is 0.5 mm, 0.7 mm, 1 mm, etc.; and the distance S2 by which the edge of the electrochemical plating 110 extends beyond the edge of the chip unit 20 is 5 μm, 8 μm, 10 μm, etc.

In some embodiments, the electrochemical plating 110 has a thickness of 5 μm to 10 μm, and/or the conductive layer 21 has a thickness of 40 μm to 60 μm, and/or the chip main body 22 has a thickness of 180 μm, and/or the DTS layer 23 has a thickness of 40 μm to 50 μm.

For example, the electrochemical plating 110 has a thickness of 10 μm, the conductive layer 21 has a thickness of 50 μm, and the DTS layer 23 has a thickness of 50 μm, without being limited thereto. The thicknesses of the electrochemical plating 110, the conductive layer 21, the chip main body 22, the DTS layer 23 and other film layers can be adjusted appropriately according to different manufacturing processes and performance requirements.

Further, another conductive layer 21 may also be stacked between the DTS layer 23 and the chip main body 22. Alternatively, the conductive layer and the DTS layer 23 may be combined into one.

Referring to FIG. 4, in some embodiments, the different types of chip units on the busbar 10 include a SiC chip unit 20a and an IGBT chip unit 20b, and may additionally include a diode chip 20c. Each of the SiC chip unit 20a and the IGBT chip unit 20b has a gate and a source both formed on a front side and a drain formed on a back side, and the SiC chip unit 20a and the IGBT chip unit 20b share the busbar 10 as the drains.

In other embodiments, the chip units 20 on the busbar 10 may include any other semiconductor chips, silicon-based chips, a plurality of SiC chips, a plurality of IGBT chips, etc. In addition, the gates, the sources and the drains of the chip units 20 may be formed on the front/back sides of the chip units 20 respectively according to design requirements.

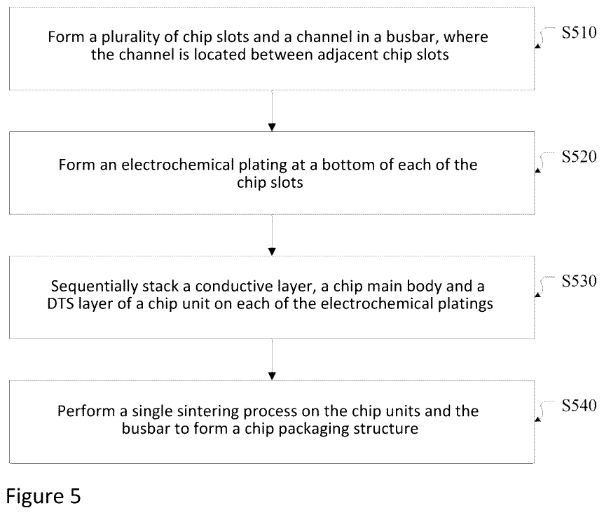

An embodiment of the present disclosure also provides a method for manufacturing a chip packaging structure as described in any of the above embodiments. FIG. 5 illustrates main steps of the method for manufacturing a chip packaging structure. With reference to FIGS. 1 to 5, the method for manufacturing a chip packaging structure according to an embodiment of the present disclosure includes the following steps.

In step S510, a plurality of chip slots 11 and a channel 12 are formed in a busbar 10, where the channel 12 is located between adjacent chip slots 11.

In step S520, an electrochemical plating 110 is formed at a bottom of each of the chip slots 11.

In step S530, a conductive layer 21, a chip main body 22 and a DTS layer 23 of a chip unit 20 are sequentially stacked on each of the electrochemical platings 110.

In step S540, a single sintering process is performed on the chip units 20 and the busbar 10 to form the chip packaging structure.

Conventionally, sintering and fixing the chip unit 20 to a substrate requires at least two sintering processes, which typically include stacking→sintering→re-stacking→re-sintering. In the manufacturing method according to the present disclosure, after each electrochemical plating 110 is formed at the bottom of the corresponding chip slot 11, laminated structures required for constituting each chip unit 20, including the conductive layer 21, the chip main body 22, the DTS layer 23, etc., are all stacked on the corresponding electrochemical plating 110, and a single sintering process is performed on the chip units 20 and the busbar 10, so that the chip units 20 are sintered and fixed in the chip slots 11 in a single process, thereby reducing the number of sintering processes, simplifying the process flow, and preventing part of the film layers of the chip units 20 from being damaged by repeated exposure to pressure and heat.

In some embodiments, the single sintering process is controlled at a pressure of 20 MPa to 25 MPa and a temperature of 200° C. to 250° C. For example, the single sintering process is performed at a pressure of 25 MPa and a temperature of 200° C., without being limited thereto. The pressure and temperature during the single sintering process are controlled to ensure that the chip units 20 are sintered and fixed in the chip slots 11 in a single process.

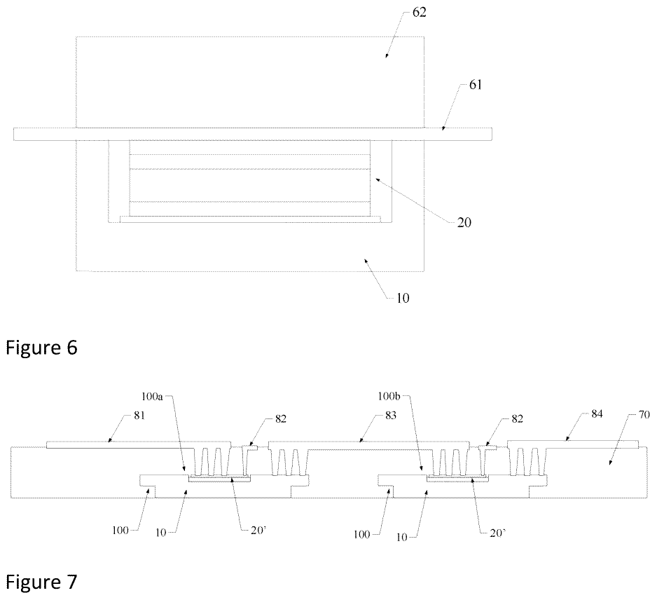

FIG. 6 illustrates the structure of the chip packaging structure during sintering. With reference to FIGS. 1 to 6, in some embodiments, during the single sintering process, a cushioned pressure head (including an insulating cushion sheet 61 and a pressure head 62) is pressed onto the chip units 20 and the busbar 10. This ensures that upper surfaces of the chip units 20 are flush with an upper surface of the busbar 10 upon completion of sintering, thereby facilitating subsequent embedding of the chip packaging structure into the circuit board.

An embodiment of the present disclosure also provides a half-bridge module for an inverter, which is implemented based on the chip packaging structure described in any of the above embodiments. FIG. 7 illustrates a sectional structure of the half-bridge module for an inverter. With reference to FIGS. 1 to 7, the half-bridge module for an inverter according to an embodiment of the present disclosure includes:
a circuit board 70;
chip packaging structures embedded into the circuit board 70, where a triode chip unit 20′ is embedded in each of the chip packaging structures; and
electrode lead-out wires, including a source lead-out wire 81 connected to a source of the triode chip unit 20′ of a first chip packaging structure 100a, gate lead-out wires 82 respectively connected to a gate of the triode chip unit 20′ of the first chip packaging structure 100a and a gate of the triode chip unit 20′ of a second chip packaging structure 100b, a series connection lead-out wire 83 for connecting a drain of the triode chip unit 20′ of the first chip packaging structure 100a in series with a source of the triode chip unit 20′ of the second chip packaging structure 100b, and a drain lead-out wire 84 connected to a drain of the triode chip unit 20′ of the second chip packaging structure 100b.

By embedding the chip packaging structures into the circuit board 70, it is possible to reduce the inductance by using the conductive layer, the insulating layer and other structures of the circuit board 70 and to reserve an area on the surface of the circuit board 70 for the arrangement of a drive circuit.

The triode chip units 20′ include, for example, a SiC chip unit and an IGBT chip unit. The SiC chip unit and the IGBT chip unit are connected to different drive circuits, so that the operation of the SiC chip unit and/or the IGBT chip unit can be controlled individually or jointly under different working conditions. For example, the SiC chip unit and the IGBT chip unit may be controlled to work together when the inverter needs to work under full-load conditions; the SiC chip unit may be controlled to work when the inverter needs to be connected to 800 V high-voltage direct current; and the IGBT chip unit may be controlled to work when the inverter is connected to 400 V low-voltage direct current.

In some embodiments, the busbar 10 of each chip packaging structure is provided with a stepped portion 100. The stepped portion 100 is used to increase the area of contact between the busbar 10 and the circuit board 70 and stabilizes the assembly of the busbar 10 and the circuit board 70.

The above is a further detailed description of the present disclosure with reference to the specific preferred implementations, and it cannot be considered that the specific implementation of the present disclosure is limited to these descriptions. For those of ordinary skill in the art of the present disclosure, several simple deductions or substitutions can be further made without departing from the concept of the present disclosure, and should be regarded as falling within the scope of protection of the present disclosure.

1. A chip packaging structure, comprising:
a busbar comprising a plurality of chip slots;
a plurality of chip units respectively embedded into the plurality of chip slots, the plurality of chip units comprising at least two different types of chip units,
wherein an electrochemical plating is arranged at a bottom of the chip slot, and the chip unit comprises a conductive layer, a chip main body, and a die top system (DTS) layer sequentially stacked on the electrochemical plating; and
a channel arranged on the busbar and located between adjacent chip slots.

2. The chip packaging structure according to claim 1,
wherein the channel has a length (L) equal to a length of the chip slot, and/or the channel has a width (W) which is ⅓ to ½ of a spacing between the adjacent chip slots, and/or the channel has a depth (D) greater than a depth of the chip slot.

3. The chip packaging structure according to claim 2,
wherein the length (L) of the channel meets: 7 mm≤L≤8 mm, and/or the width (W) of the channel meets: 1 mm≤W≤1.5 mm, and/or the depth (D) of the channel meets: 0.25 mm≤D≤0.5 mm.

4. The chip packaging structure according to claim 1,
wherein an area of a projection of the electrochemical plating on the bottom of the chip slot is greater than an area of a projection of the chip unit on the bottom of the chip slot, and the electrochemical plating is spaced from a peripheral wall of the chip slot.

5. The chip packaging structure according to claim 4,
wherein a spacing (S1) between the chip unit and the peripheral wall of the chip slot meets: 0.5 mm≤S1≤1 mm, and/or a distance (S2) by which an edge of the electrochemical plating extends beyond an edge of the chip unit meets: 5 μm≤S2≤10 μm.

6. The chip packaging structure according to claim 1,
wherein the electrochemical plating has a thickness of 5 μm to 10 μm, and/or the conductive layer has a thickness of 40 μm to 60 μm, and/or the chip main body has a thickness of 180 μm, and/or the DTS layer has a thickness of 40 μm to 50 μm.

7. The chip packaging structure according to claim 1,
wherein the plurality of chip units on the busbar comprise a SiC chip unit and an IGBT chip unit,
wherein each of the SiC chip unit and the IGBT chip unit has a gate and a source both formed on a front side and a drain formed on a back side, and the SiC chip unit and the IGBT chip unit share the busbar as the drains.

8. A half-bridge module for an inverter, the half-bridge module comprising:
a circuit board;
two chip packaging structures according to any claim 1 comprising a first chip packaging structure and a second chip packaging structure embedded into the circuit board, wherein a triode chip unit is embedded in each of the chip packaging structures; and
electrode lead-out wires comprising a source lead-out wire connected to a source of the triode chip unit of the first chip packaging structure, gate lead-out wires respectively connected to a gate of the triode chip unit of the first chip packaging structure and a gate of the triode chip unit of the second chip packaging structure, a series connection lead-out wire for connecting a drain of the triode chip unit of the first chip packaging structure in series with a source of the triode chip unit of the second chip packaging structure, and a drain lead-out wire connected to a drain of the triode chip unit of the second chip packaging structure.

9. The half-bridge module according to claim 8, wherein a busbar of each of the chip packaging structures is provided with a stepped portion.

10. A method for manufacturing a chip packaging structure comprising:
forming a plurality of chip slots and a channel in a busbar, wherein the channel is located between adjacent chip slots;
forming an electrochemical plating at a bottom of each of the chip slots;
sequentially stacking a conductive layer, a chip main body, and a die top system (DTS) layer of a chip unit on each of the electrochemical platings; and
performing a single sintering process on the chip units and the busbar to form the chip packaging structure.

11. The method according to claim 10, comprising:
performing the single sintering process at a pressure of 20 MPa to 25 MPa and a temperature of 200° C. to 250° C.

12. The method according to claim 10, comprising:
during the single sintering process, pressing a cushioned pressure head onto the chip units and the busbar.
